(19) United States
(12) Patent Application Publication
(10) Pub. No.: US 2008/0197440 A1
(43) Pub. Date: Aug. 21, 2008

(54) Nonvolatile Memory

(75) Inventors: Seisuke Nigo, Chiba (JP); Takayuki Ohnishi, Ibaraki (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MISUZU R & D LTD., Tsukuba-shi, Ibaraki (JP)

(21) Appl. No.: 11/916,335

(22) PCT Filed: Jun. 2, 2005
(86) PCT No.: PCT/JP2005/010190

§ 371 Date: Mar. 13, 2008

(51) Int. Cl. H01L 29/47

(52) U.S. Cl. 257/485; 257/471; 257/E29.148

(57) ABSTRACT

To provide a nonvolatile memory which realizes nonvolatile characteristic similar to a flash memory and a high-speed access equivalent to SRAM, has an integration degree exceeding that of DRAM, requires low voltage and low power consumption, and can be driven by a small-size battery, there are provided: (1) a non-volatile memory, including: a pair of metal electrodes; and a nano-hole-containing metal oxide film having a film thickness of 0.05 μm to 5 μm, which has a honeycomb structure and is provided between the pair of metal electrodes in a Schottky junction state, to use an interface state produced in a partition wall of the nano-hole-containing metal oxide film as a memory charge holder; and (2) a non-volatile memory, including: a substrate electrode; a nano-hole-containing metal oxide film formed by anodic oxidation of a surface of the substrate electrode; and a metal electrode formed to an upper end portion of a partition wall of the nano-hole-containing metal oxide film by Schottky junction, in which the nano-hole-containing metal oxide film has a structure in which a plurality of double Schottky barriers are formed in parallel.

### TECHNICAL FIELD

The present invention relates to a non-silicon nonvolatile memory. More particularly, the present invention relates to a nonvolatile memory using interface states produced in partition walls of a nano-hole-containing metal oxide film as memory charge holders.

### BACKGROUND ART

There have been used general-purpose random access memories that are a static RAM (SRAM: random access read/write memory which requires no memory holding (refresh) operation), a dynamic RAM (DRAM: random access read/write memory which requires refresh operation), and a flash memory (nonvolatile semiconductor memory having both a feature of a RAM and a feature of a ROM capable of holding data after the power-off).

In addition to the defect that the SRAM is volatile, a capacity thereof cannot be increased because it is difficult to realize high integration thereof. However, high-speed access is possible, so the $RAM is used for a cash memory and the like. In addition to the defect that the DRAM is volatile, the DRAM requires refresh operation at the time of reading because the DRAM is a data destructive read type. However, the DRAM has been used for a main memory of a personal computer because the DRAM has a characteristic in that the increase in capacity can be realized

On the other hand, the flash memory has widely been used as the nonvolatile memory which does not lose memory contents thereof even after the power-off. Although a write time of the flash memory takes 1000 nanoseconds which is 200 times longer than that of the DRAM, the flash memory is used to store relatively small-capacity data because the flash memory has characteristics of the integration and nonvolatility. However, the conventional memories are unsatisfactory in the ubiquitous computing age or the high-speed processing age in which information devices include various devices as well as personal computers. Therefore, the development of a so-called universal memory having the respective advantages of the SEAM, the DRAM, and the flash memory has been expected for a long time.

In order to develop the universal memory the development of nonvolatile memories such as a ferroelectric RAM (FeRAM; ferroelectric memory), a magnetic RAM (MRAM): memory using a memory element exhibiting a magnetoresistance effect), and an ovonics unified memory (OUM: semiconductor memory using a phase change film for a memory element) has been carried out.

In the case of the FeRAM, the defect that the DRAM is volatile is solved by the use of a ferroelectric capacitor and a reduction in voltage is achieved by a write time of 50 nanoseconds. However, rewrite operation is necessary because of being the data destructive read type memory, so a read time becomes longer. A two-transistor two-capacitor type memory cell is in practical use, but there is a limit on an increase in capacity because of a complicated structure.

The MRAM is suitable for high-speed access. However, because of the use of change in magnetic field, a specific manufacturing process is employed, so costs become higher. For the increase in capacity, it is necessary to reduce a size of a sense amplifier. Therefore, there is a problem that a reduction in write current is required.

The OUM is a new recording medium made of chalcogenide alloy, uses the phenomenon that crystallization upon current heating to 600° C. causes a reduction in electrical resistance and amorphization upon cooling causes a return to a high resistance, and has a simple structure of a bipolar element. Therefore, the OUM has been expected as a nonvolatile memory which may replace the flash memory. However, writing is performed by current heating, so there is a concern in reliability. A voltage application time at the time of writing is long, which hinders an increase in speed. Thus, the practical use has not been established.

As described above, the conventional nonvolatile memories are different from one another and none of the nonvolatile memories provides a decisively advantageous technique.

Up to now, with respect to the nonvolatile memory, a metal-oxide semiconductor field effect transistor (MOSFET) memory is generally used as the flash memory. FIG. 1 shows a conventional MOSFET memory. The MOSFET memory includes three electrodes: a gate electrode 21, a source electrode 29, and a drain electrode 25. A floating gate 24, an oxide film 23, and a control gate 22 which are successively stacked are connected with a drain junction region 26 and a source junction region 28 which are provided in a substrate 27 through a tunnel oxide film 30. Electrons are trapped in and extracted from the floating gate 24 through the tunnel oxide film 30. Therefore, when a voltage is applied to the gate electrode, a conduction channel is formed in an upper surface portion of the substrate 27 or the formed conduction channel is eliminated, so an electrical connection between the drain electrode 25 and the source electrode 29 is turned on or off to store information. That is, the conventional MOSFET memory uses a two-step control system and only uses a tunnel effect in order to inject/extract electrons to/from the floating gate. A memory current circuit does not directly use the tunnel effect. Thus, there is a limit on an increase in speed and a reduction in voltage.

Recently, research and development of a tunnel memory whose power consumption is reduced and speed is increased have been carried out. The development of a memory for mobile communication device which is called a “direct tunnel memory” is announced by Fujitsu Laboratories Ltd. as an example of the tunnel memory. This memory uses a direct tunnel effect of an extremely thin gate insulating film for logic LSI in view of low power consumption and the storage of a large amount of data. The memory is intended to be used as a next-generation G-bit RAM whose standby power consumption is equal to or smaller than 1/10000 of that of the DRAM. Even in the case of the memory, two kinds of gates, that is, a control gate and a floating gate are necessary.

Various nonvolatile memories using a Schottky barrier or the tunnel effect have been proposed in patent documents. For example, a nonvolatile memory in which a metal silicide film forming a Schottky barrier diode and a silicon film is provided is proposed as the nonvolatile memory using the Schottky barrier (see Patent Document 1), a nonvolatile memory in which an insulating layer through which electrons can directly tunnel in a quantum-mechanical manner is provided is proposed as the nonvolatile memory using the tunnel effect (see Patent Document 2), and a nonvolatile memory having a structure in which electrons captured by traps are tunnel-emitted through an insulating film is provided is proposed as the nonvolatile memory using the tunnel effect (see Patent Document 3).

However, Patent Documents 1 to 3 relate to the techniques using the tunnel effect to inject/extract electrons to/from the floating gate of the MOSFET nonvolatile memory through the insulating film In any case, inverted channel formation is used to control a memory current. That is, the tunnel effect is not directly used for the on/off of the memory current, so a current on/off ratio cannot be significantly improved. Therefore, there is a limit on the increase in speed and the reduction in voltage.

Patent Document 1: JP 2913752 B

Patent Document 2: JP 2002-289709 A

Patent Document 3: JP 2003-68893 A

### DISCLOSURE OF THE INVENTION

The present invention has been made in view of the above-mentioned circumstances and an object of the present invention is to provide a low-voltage and low-power-consumption nonvolatile memory which realizes high-speed access equivalent to an SRAM, has an integration degree exceeding that of a DRAM, and can be driven by a small-size battery.

As a result of intensive studies that had been made in order to achieve the object, the inventors of the present invention found the following fact. When a nano-hole-containing metal oxide film is formed to have a honeycomb shape, interface states are produced in partition walls thereof at high density. Therefore, when the metal oxide film is set in a Schottky junction state, trap charges such as electrons trapped in the interface states become control charges for directly turning on/off a memory current and can be used as memory charges at the same time.

That is, the present invention is a honeycomb type FET random access memory (HoFET-RAM), and provides:

(1) a non-volatile memory, including:

a pair of metal electrodes; and

a nano-hole-containing metal oxide film having a film thickness of 0.05 μm to 5 μm, which has a honeycomb structure and is provided between the pair of metal electrodes in a Schottky junction state, to use an interface state formed in a partition wall of the nano-hole-containing metal oxide film as a memory charge holder; and

(2) a non-volatile memory, including:

a substrate electrode;

a nano-hole-containing metal oxide film formed by anodic oxidation of a surface of the substrate electrode; and

a metal electrode formed to an upper end portion of a partition wall of the nano-hole-containing metal oxide film by Schottky junction,

in which the nano-hole-containing metal oxide film has a structure in which a plurality of double Schottky barriers are formed in parallel.

In the nonvolatile memory according to the present invention, information is stored using a trap charge and simultaneously double Schottky barriers are destroyed or restored. Therefore, a current on/off ratio is, for example, a high value equal to or larger than 10⁶. An operating voltage of the memory depends on a metal type of a Schottky electrode to be used. When gold is used, an applied voltage at the time of reading is equal to or smaller than 0.2 V, an applied voltage at the time of writing is approximately 1 V at which a Fowler-Nordheim tunnel current (hereinafter referred to as a “FN tunnel current”) generates, and a voltage at the time of deleting is approximately −1 V. Therefore, the consumption power of the memory is small, so small-size battery driving is possible.

According to the present invention, electrons excited by hot electrons of the FN tunnel current are used as triggers for writing, so a write speed is higher as compared with a conventional system for injecting electrons to a capacitor and thus high-speed switching is possible.

### BRIEF DESCRIPTION OF THE DRAWINGS

FIG. 1 is a schematic cross sectional view showing a structure of a conventional MOSFET nonvolatile memory.

FIG. 2 is a schematic cross sectional view showing a structure (corresponding to one cell) of a nonvolatile memory according to the present invention.

FIG. 3 shows a change in current-voltage characteristic of the nonvolatile memory according to the present invention.

FIGS. 4(a) and (b) schematically shows cross sections of two nano-holes and partition walls and changes in Schottky barriers which are caused by electron trapping in the nonvolatile memory according to the present invention.

FIG. 5 is a transmission electron microscope picture showing an aluminum anodic oxide film formed in Example 1.

FIG. 6 shows an example of a memory element resistance value measuring circuit for obtaining example data of the present invention.

FIG. 7 is a graph showing measured resistance value change data.

FIG. 8 is a circuit diagram showing a memory device to which the nonvolatile memory according to the present invention is applied.

### DESCRIPTION OF SYMBOLS

11, 41 lead electrode
12, 42 metal electrode formed by Schottky junction
13, 43 nano-hole-containing metal oxide film
14, 44 substrate electrode
15, 45 nano-hole filled with insulating material
16, 46 insulating film
17, 47 nano-hole partition wall
18, 48 silicon substrate
21 gate electrode
22 control gate
23 oxide film
24 floating gate
25 drain electrode
26 drain junction region
27 substrate
28 source junction region
29 source electrode
30 tunnel oxide film
49a double Schottky barrier
49b double Schottky barrier in which, due to trap charge, the thickness thereof is reduced to enter a tunnel state
50 trap electron

### BEST MODE FOR CARRYING OUT THE INVENTION

According to the present invention, there is provided a nonvolatile memory in which a nano-hole-containing metal oxide film which has a film thickness of 0.05 μm to 5 μm and includes a honeycomb structure is formed between a pair of metal electrodes in a Schottky junction state, to use interface states produced in partition walls of the nano-hole-containing metal oxide film as memory charge holders. In addition, according to the present invention, there is provided a nonvolatile memory including a substrate electrode, a nano-hole-containing metal oxide film formed by anodic oxidation of a surface of the substrate electrode, and a metal electrode formed to an upper end portion of a partition wall of the nano-hole-containing metal oxide film by Schottky junction. The nano-hole-containing metal oxide film includes a structure in which a plurality of double Schottky barriers are formed in parallel.

A generally-used Schottky diode is in a non-electrical connection state at an applied voltage of approximately 0.3 V because of Schottky barrier. When a voltage equal to or higher than the height of the Schottky barrier, for example, a voltage of 5 V is applied in the forward direction, a surge current flows through the Schottky barrier to make an electrical connection. When the applied voltage is reduced to a value equal to or lower than the height of the barrier, the diode returns to the non-electrical connection state. However, when an interface state is located in a Schottky junction portion, this acts as a trap level or a recombination center, so an abnormal phenomenon such as a leakage current other than a regular current or a hysteresis appears. Therefore, it is necessary to minimize an interface state density. In addition to the above-mentioned example, according to the common sense in the field of semiconductor, the interface state becomes uncontrollable disturbance, so a best method is considered to minimize the interface state density. Thus, the invention in which the interface state is positively used as the charge holder has not been made.

In the present invention, the interface state is not directly controlled but the interface state is confined in a three-dimensional nanostructure to control a location at which the interface state exists, thereby substantially controlling the interface state.

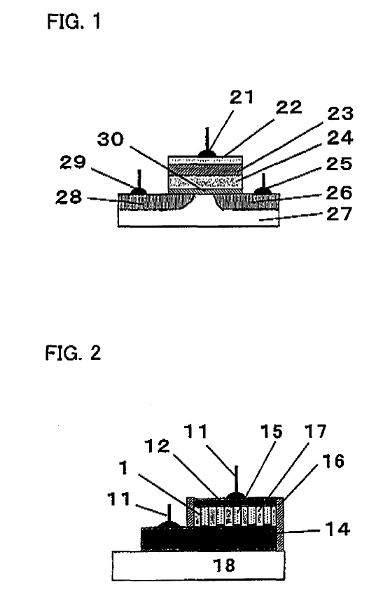

In other words, unlike the conventional case (see FIG. 1), in the nonvolatile memory according to the present invention, the Schottky electrode is not two-dimensionally joined, the metal oxide film including the nano-holes is formed to have the honeycomb structure, and an upper portion of each of partition walls having a honeycomb lateral cross sectional shape and the metal electrode are provided in the Schottky junction state (see FIG. 2). The partition wall (corresponding to n-type semiconductor) of the nano-hole-containing metal oxide film includes interface states caused by lattice defects equal to or larger than 10¹⁶/cm³ which are formed at the time of anodic oxidation. However, the electrode is joined to the upper portion of each of the partition walls having the honeycomb shape, for example, a convex portion whose width is 20 nm, of the upper end portion of each of the partition walls. Therefore, the number of interface states included in a Schottky electrode junction portion is equal to or smaller than approximately 1/10 of a total thereof. Remaining interface states corresponding to approximately 9/10 of the total are perpendicularly stacked and aligned in an electrode direction without having contact with the electrode and opposed to both surfaces of the partition wall. Thus, the interface states located in the perpendicular portion of the partition wall do not block a current flowing through the Schottky electrode.

Electrons trapped in the interface states which are located in the perpendicular portion of the partition wall and correspond to approximately 9/10 repel one another by coulomb force and then are unevenly distributed in both surfaces of the partition wall. Therefore, when the nano-hole is filled with an insulating material such as SiO₂ to make an inner surface thereof in an insulating state, a metastable state is maintained, so the electrons act as tetastable trap charges sandwiching both sides of the central oxide film of the center portion of the partition wall. When the electrons are trapped in the interface states, a potential of the central layer of the partition wall which is sandwiched by the trap charges is reduced by the trap charges to curve the potential. Then, the Schottky barrier is thinned and enters a tunnel state, thereby making an electrical connection between electrodes.

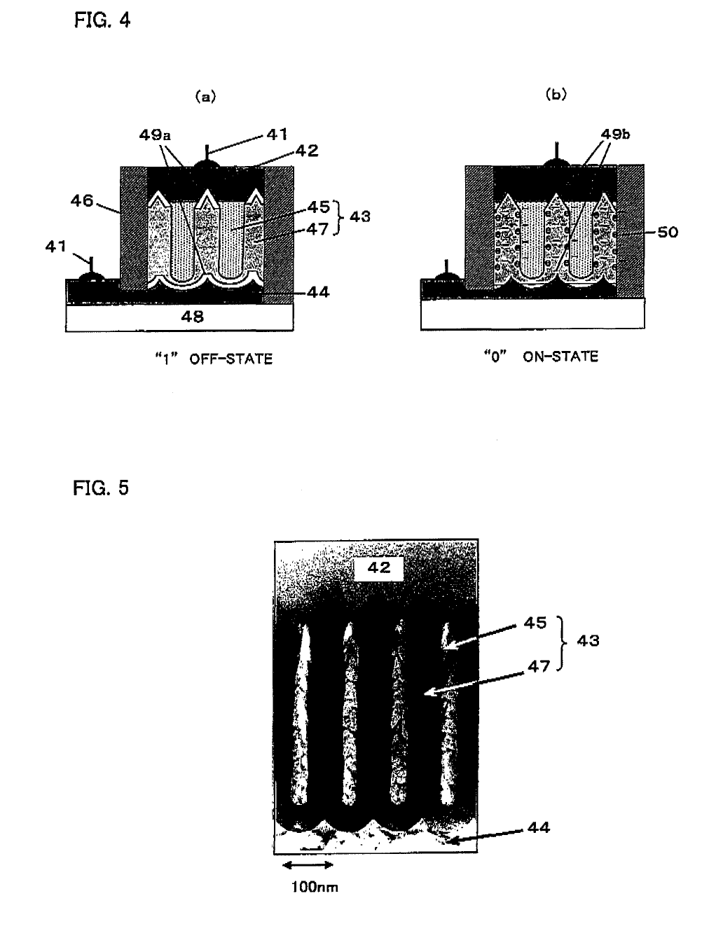

The sequential operation is summarized as follows. When a voltage of approximately 1 V is applied, an FN current flows through the double Schottky barriers. Electrons excited by hot electrons of the current are trapped in the interface states of the partition wall of the oxide film to become metastable trap charges. A potential of a central layer of the partition wall is reduced by local electric fields of the trap charges, so each of the double Schottky barriers (49a in FIG. 4(a)) enters the tunnel state (49b in FIG. 4(b)), thereby making the electrical connection state.

The electrical connection state is the metastable state. Even when a power supply is turned off, trap electrons stay in the interface states. The electrical connection state is held until the trap electrons are extracted to a lower electrode by a reverse voltage.

In other words, according to the present invention, the trap electrons are injected to or extracted from the interface states produced in the partition walls of the nano-hole-containing metal oxide film to destroy or restore the Schottky barriers. Therefore, switching between the electrical connection state and the non-electrical condition is performed to store and hold information of “0” or “1”. Thus, the nonvolatile memory according to the present invention does not require a gate electrode and an additional capacitor structure because the memory current is directly controlled by the trap charges. That is, according to the present invention, the non-volatile memory including the very simple single transistor having the two electrodes (substrate electrode 44 and metal electrode 42 provided by Schottky junction) is realized,

In the present invention, a lattice defect density of the partition wall of the nano-hole-containing metal oxide film is preferably equal to or larger than 10¹⁶/cm³, more preferably equal to or larger than 10¹⁸/cm³. When the lattice defect density is smaller than 10¹⁴/cm³, the number of trap charges is insufficient, so the Schottky barrier is not sufficiently thinned. Therefore, it is unlikely to make the electrical connection state.

The thickness of the nano-hole-containing metal oxide film is in a range of 0.05 μm to 5 μm, preferably in a range of 0.1 μm to 1 μm. When the thickness of the nano-hole-containing metal oxide film is smaller than 0.05 μm, a leak current increases. The thickness equal to or larger than 5 μm is not preferable because it is difficult to generate the FN current.

The nano-hole-containing metal oxide film can be obtained by anodic oxidation of the surface of a metal such as aluminum or titanium.

A known method can be employed as the anodic oxidation method and thus there is no specific limitation. It is preferable that an electrolytic solution contain an acid whose concentration is, for example, 1% to 5%, a temperature thereof be adjusted to 0° C. to 50° C., and a voltage applied thereto be controlled to a predetermined value in a range of 10 V to 150 V. Although the acid is not particularly limited, it is preferable to use 1% to 5% oxalic acid, sulfuric acid, phosphoric acid, or the like. In particular, a mixture solution whose mixture ratio of [oxalic acid whose concentration is 1% to 5%]:[Esulfuric acid whose concentration is 1% to 5%] is 2 to 4:1 to 3, particularly, 3:2 is preferable.

In order to form a nano-hole-containing metal oxide film having a regular fine structure, it is preferable to use a high-purity aluminum whose purity is equal to or larger than 99.0%, preferably 99.5%, such as a JIS 1000 series, and a surface thereof is smooth.

A diameter of the nano-hole provided in the metal oxide film by self-organized formation is preferably 10 nm to 150 nm, more preferably 30 nm to 60 nm. When the diameter is equal to or smaller than 10 nm, it is difficult to make the electrical connection state. The reason for this is probably as follows: the thickness of the partition wall becomes thinner in proportion to the nano-hole diameter, so the interface states serving as the charge holders are overlapped with a channel layer located at the center of the partition wall to thin the channel layer, whereby a channel current does not flow. On the other hand, when the diameter is equal to or larger than 150 nm, the thickness of the partition wall becomes thicker in proportion to the diameter, charge holder layers of the interface states are far separated from the channel layer located at the center of the partition wall, so a size effect caused by local electric fields becomes insufficient. In other words, a potential of a central portion of the partition wall is not sufficiently reduced by the trap charges of the interface states, so it is difficult to generate a tunnel effect due to a reduction in thickness of the Schottky barrier and to make the electrical connection state.

The diameter of the nano-hole can be controlled by adjusting a kind of acid used for the electrolytic solution for anodic oxidation. When sulfuric acid is used for the electrolytic solution, the diameter of the nano-hole is minimized. The diameter of the nano-hole increases in the order of a mixture of oxalic acid and phosphoric acid, oxalic acid, and phosphoric acid. In particular, a nano-hole formed using an electrolytic solution of 2% to 4% oxalic acid is preferable because the nano-hole has a diameter of 30 nm to 60 nm and is perpendicular to a surface.

In the nonvolatile memory according to the present invention, a film made of metal such as gold, aluminum, nickel, titanium, tin, or tungsten is formed to the upper end portion of the partition wall of the nano-hole-containing metal oxide film by Schottky junction using vapor deposition or sputtering to be used as one of metal electrodes, and a base metal made of aluminum, titanium, or the like is used as the other electrode. Gold or aluminum is preferable as metal for Schottky junction. With such a structure, there is an advantage in that an operating voltage is stabilized.

In the nonvolatile memory according to the present invention, a two-dimensional array of the nano-holes formed in the metal oxide film is divided by grooves to produce memory cells, each including two or three or more nano-holes, which are insulated from one another. Therefore, the two-dimensional array of the nano-holes can be used as a memory cell array without any modification.

The structure of the non-volatile memory according to the present invention will be described in more detail with reference to the drawings. FIG. 2 is a schematic cross sectional view showing the structure of the nonvolatile memory according to the present invention. FIG. 2 is a structural view showing a memory cell including five nano-holes of a large number of nano-holes formed in honeycomb shape in the nano-hole-containing metal oxide film.

In FIG. 2, a substrate electrode 14 is made of aluminum or the like. A nano-hole-containing metal oxide film 13 formed by anodic oxidation of the substrate electrode 14 is located on a surface side of the substrate electrode 14. A Schottky electrode 12 formed by vapor deposition, sputtering, or the like is provided on upper end portions of partition walls of the nano-hole-containing metal oxide film. The Schottky electrode 12 is connected with a lead electrode 11. A Schottky barrier is located between the partition wall of the nano-hole-containing metal oxide film 13 and each of the Schottky electrode 12 and the substrate electrode 14, so an electrical connection between the electrodes is blocked by double Schottky barriers.

In the case where gold is used for the Schottky electrode, when a low voltage, for example, a voltage of 0.2 V is applied between the Schottky electrode 12 and the substrate electrode 14, a current does not flow between the electrodes which are the Schottky electrode 12 and the substrate electrode 14 because of a Schottky barrier formed in a junction surface between the Schottky electrode 12 and the partition wall of the nano-hole-containing metal oxide film 13, However, when a voltage is slightly higher than the low voltage, for example, a voltage of 1 V is applied, an FN tunnel current flows through the Schottky barrier. Then, when electrons excited by hot electrons generated by the current are trapped in the interface states of the partition walls of the nano-hole-containing metal oxide film, potentials of nano-hole partition walls 47 are reduced by trap charges. Therefore, the Schottky barrier located between the electrodes which are the Schottky electrode 12 and the substrate electrode 14 is thinned and then enters a tunnel state to make an electrical connection, so a current of ten and several mA flows at a voltage of 0.2 V. The electrical connection state is a metastable state, so it is maintained even when the applied voltage is set to zero.

On the other hand, when a voltage of −1 V is applied between the electrodes which are the Schottky electrode 12 and the substrate electrode 14, the trapped electrons are extracted to the lower electrode side. Then, the Schottky barrier is restored, so a state between the electrodes which are the Schottky electrode 12 and the substrate electrode 14 is returned to an original non-electrical connection state.

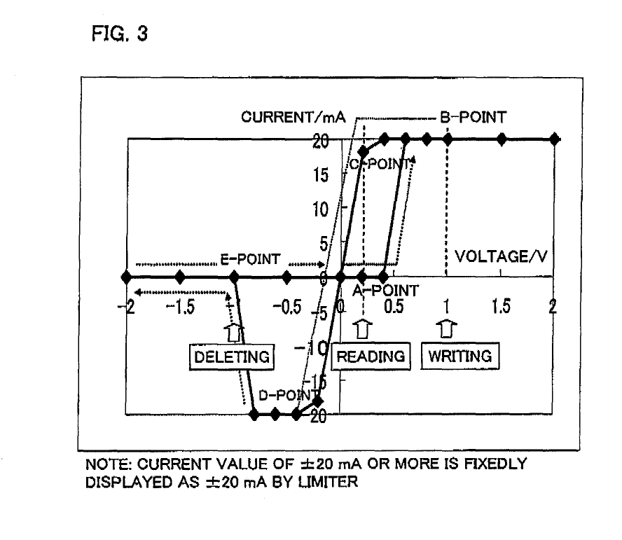

FIG. 3 shows a change of a current-voltage characteristic of the non-volatile memory according to the present invention. When gold is used as Schottky junction metal, as shown in FIG. 3, a voltage of 1 V is applied between the electrodes which are the Schottky electrode 12 and the substrate electrode 14 to write memory contents (B-point) and a voltage of −1 V is applied between the same electrodes to delete the memory contents (E-point). When a state where a current of approximately 17 mA flows in the case where a voltage of 0.2 V is applied between the same electrodes is assumed to be a “0” on-state (C-point) and when a state where a current does not flow in the same case is assumed to be a “1” off-state (A-point), memory contents can be read out.

Even when aluminum is used as a metal for the metal electrode, the same characteristic is fundamentally exhibited.

As described above, the present invention employs one-step control for destroying and restoring the double Schottky barriers between the electrodes only by the injection and extraction of trap electrons to directly turn on/off a memory current and store information at the same time. Therefore, the number of control factors is small and a response is quick.

The double Schottky barriers on a memory current path are directly on/off-controlled, so a current on/off ratio is equal to or larger than 10⁶, which is very high. Therefore, even when an applied voltage at the time of reading is significantly reduced, the memory current can be sufficiently ensured. In other words, according to the present invention, low-voltage driving is fundamentally possible. Note that, in order to prevent a faulty operation caused by trap electrons generated by an impulse electromagnetic wave such as a noise from an outside, it is preferable to electromagnetically shield the entire memory cell.

FIGS. 4 are a schematic cross sectional view showing the case where a memory cell has two nano-holes and a schematic view showing changes in trap electrons and Schottky barriers. The operation principle of the present invention will be described with reference to FIGS. 4 and 3.

FIG. 4(a) shows a state (“1” off-state) of a memory cell at the A-point shown in FIG. 3. A nano-hole-containing metal oxide film 43 includes nano-holes 45 each having a diameter of 10 nm to 150 nm, preferably 30 nm to 60 nm, which are arranged substantially perpendicular to the upper electrode. As a result, nano-hole partition walls 47 in which interface states for trapping electrons are produced are arranged in parallel in an electrode direction. This is the same as the state where two very small capacitors are arranged facing each other in each of the nano-hole partition walls 47. A state between a convex end portion of each of the nano-hole partition walls 47 and the Schottky electrode 42 is the non-electrical connection state because of the Schottky barrier. The nano-hole-containing metal oxide film 43 is formed on a substrate electrode 44 by anodic oxidation of aluminum or the like of the substrate electrode 44. A state between each of the nano-hole partition walls 47 and the substrate electrode 44 is also the non-electrical connection state because of the Schottky barrier. In other words, the electrode 42 and the electrode 44 are electrically separated from each other by double Schottky barriers 49a and the A-point shown in FIG. 3 indicates that the state between the electrode 42 and the electrode 44 is the non-electrical connection state at an applied voltage of 0.2 V. FIG. 4 shows an example in which three pairs of double Schottky barriers are formed in parallel.

In this embodiment, in the case of an aluminum anodic oxide film formed by a method described in Example 1, as shown in FIG. 5, the diameter of each of the nano-holes 45 is approximately 40 nm and all the nano-holes 45 are formed substantially perpendicular to the substrate electrode 44. Similarly, the nano-hole partition walls 47 are formed substantially perpendicular to the substrate electrode 44 and have a uniform wall thickness, meaning that a fine structural necessary condition for using the nano-hole partition wall 47 for a charge holder and a channel is satisfied.

As shown in FIG. 3, when a write voltage applied between electrodes is increased to approximately 1 V, the A-point is shifted to the B-point on a hysteresis curve. This phenomenon exhibits that the FN tunnel current flows through the Schottky barriers because the applied voltage of 1 V corresponds to a voltage caused when the FN tunnel current flows through the Schottky barrier located between the nano-hole partition wall 47 and each of the Schottky electrode 42 and the substrate electrode 44. Electrons passing through the Schottky barrier are so-called hot electrons having excess energies Then, electrons in the valence band of the nano-hole partition wall 47 are excited to emit the energies. The nano-hole partition wall 47 includes high-density interface states, so the excited electrons are trapped in the interface states.

This state is schematically shown in FIG. 4(b) (“0” on-state). As shown in FIG. 4(b), trap charges such as the electrons trapped in the nano-hole partition wall 47 produce local electric fields orthogonal to a Schottky junction surface to curve potential surfaces. As a result, a thickness of the Schottky barrier in the electrode direction reduces, so the Schottky barrier enters a tunnel state.

In other words, the thickness of the Schottky barrier reduces at a central layer portion of the nano-hole partition wall 47 as shown in FIG. 4(b), so the Schottky barrier enters the tunnel state, thereby making the electrical connection (on) state.

The state shown in FIG. 4(b) is the metastable state. Therefore, even when the applied voltage is set to zero, the electrical connection state is held because the trap electrons stay in the interface states. In other words, a point moves on a metastable line joining the C-point and the D-point through an origin on the hysteresis curve shown in FIG. 3.

The C-point shown in FIG. 3 indicates an on-state at an applied voltage of 0.2 V in the presence of the trap electrons. Memory contents are determined based on a current value difference between the A-point and the C-point. In the C-point, a detection current of ten and several mA flows at approximately 0.2 V. Because the trap electrons are not extracted at the applied voltage of approximately 0.2 V, the on-state is not changed by the read operation. On the other hand, in the A-point, the detection current is equal to or smaller than several ten pA and this corresponds to the off state. Because the trap electrons are not generated at the applied voltage of approximately 0.2 V, the off-state is not changed by the read operation.

Memory deletion is performed at the E-point shown in FIG. 3. A voltage at the E-point is set to a voltage sufficient to extract the trap electrons. For example, when a voltage of −1 V is applied, the trap electrons are extracted to the lower electrode to lose trap charges. Then, the thickness of the Schottky barrier is returned to an original thickness to become the off-state. This state is the stable state.

As described above, in the nonvolatile memory according to the present invention, all functions necessary for the memory are sequentially operated based on the simple principle and high-speed switching between the “1” off-state shown in FIG. 4(a) and the “0” on-state shown in FIG. 4(b) is performed.

In the nonvolatile memory according to the present invention, a memory cell can include three or more nano holes. In this case, the number of channels of the memory cell becomes larger and an on-current increases in proportion thereto.

In principle, one memory cell functions when it has one channel. Therefore, a minimum size of the memory cell is twice a nano-hole interval (0.1 μm) and a calculated minimum cell area is 0.04 μm².

### EXAMPLE

Next, the present invention will be described in more detail by means of examples. The present invention is not limited to the examples.

### Example 1

A surface of an aluminum whose purity was 99.99%, diameter was 2 inφ, and thickness was 0.5 mm was polished for approximately four minutes by chemical mechanical polishing (CMP) or electrolytically polished in a mixture bath in which a ratio of perchloric acid and ethanol was 1:4. After that, a cathode was located on a surface of the sample in a 3%-oxalic-acid bath and constant voltage anodic oxidation was performed for several hours at a bath temperature of 20° C. and 40 V while a bath solution was stirred. Then, an oxide film was dissolved in a mixture bath containing deionized water, chronic acid, and phosphoric acid at a bath temperature of 60° C. Then, the anodic oxidation was performed again in the above-mentioned condition for several minutes to form a nano-hole-containing aluminum oxide film having a thickness of approximately 0.3 μm in which thin holes each having a diameter of approximately 35 nm were arranged at a regular interval of 100 nm.

A surface of the sample (aluminum substrate) was bonded to a silicon substrate whose thickness was 0.5 mm and dried. After that, a slit whose width was 1 μm (column directional slit) was formed for every 20 columns of the thin holes arranged at a pitch of 100 nm at a depth at which the lower surface of the aluminum substrate was completely cut.

Next, a slit whose width was 1 μm (row directional slit) was formed for every 20 columns of the thin holes arranged at a pitch of 100 nm in a direction orthogonal to the slit at a depth at which the aluminum oxide film was completely cut. An SiO₂ film was formed as an insulating film in grid-shaped slit grooves by sputtering.

The SiO₂ insulating film was selectively etched to expose upper end portions of the partition walls of the nano-holes of the aluminum oxide film and then a gold film whose thickness was 100 nm was formed as an upper electrode by sputtering for each cell. By the above-mentioned processing, a two-dimensional memory cell array was completed in which cells were electrically connected with one another through the substrate electrode in the column direction and insulated from one another in the row direction. Upper electrodes were connected with one another in the row direction by wire bonding to complete a two-dimensional memory cell. FIG. 2 is a cross sectional view showing a cell of the produced memory cell.

A nano-hole thickness in the aluminum oxide film was 0.3 in and a nano-hole diameter was 35 nm. A gold electrode thickness was 100 nm and a cell area was 4 μm².

The aluminum oxide film thickness, the electrode thicknesses, the nano-hole array pitch, the nano-hole diameter, and the cell area were observed and measured using a scanning electron microscope (SEM) or a transmission electron microscope (TEM). FIG. 5 is a picture (magnification: 300000 times) obtained in the case where the cross section of the aluminum oxide film formed in Example 1 was observed using a transmission electron microscope. As is apparent from FIG. 5, the aluminum oxide film has regular nano-hole partition walls.

### Example 2

Instead of the aluminum substrate in Example 1, a substrate (2 inφ and 0.5 mm in thickness) was used in which an aluminum sputtering film whose thickness was 20 μm was formed on an SiO₂ film produced by thermal oxidation of a silicon substrate and the same processes as those in Example 1 were performed.

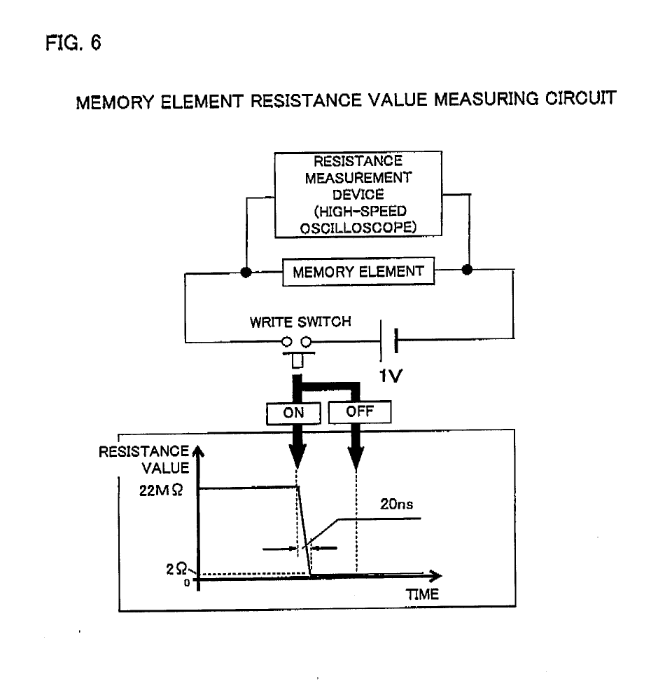

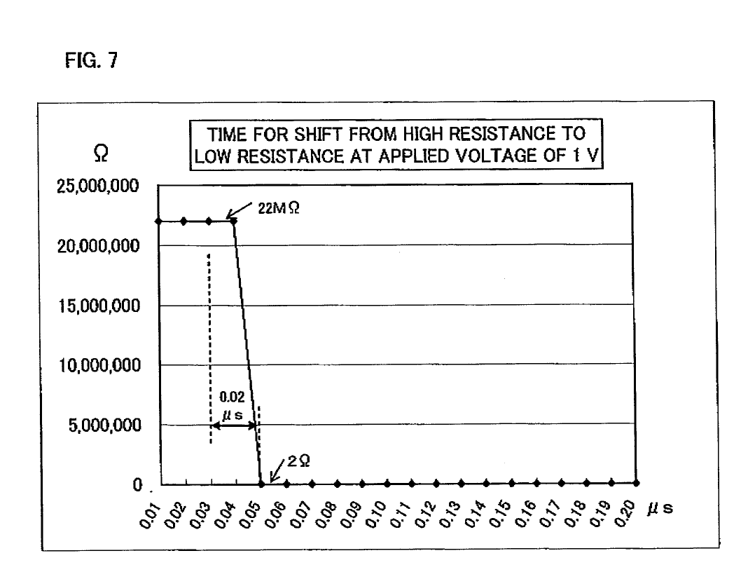

A resistance value measuring circuit shown in FIG. 6 was used. A change in resistance value of the memory element obtained in Example 1 was measured using a high-speed oscilloscope. FIG. 7 shows data indicating the change in resistance value. As is apparent from FIG. 7, a time for shift from a high resistance (22 MΩ) to a low resistance (2Ω) when a voltage of 1 V was applied between electrodes was 0.02 μs (20 ns). Thus, it is apparent that a write time is equal to or smaller than 50 ns even when a time lag is taken into account.

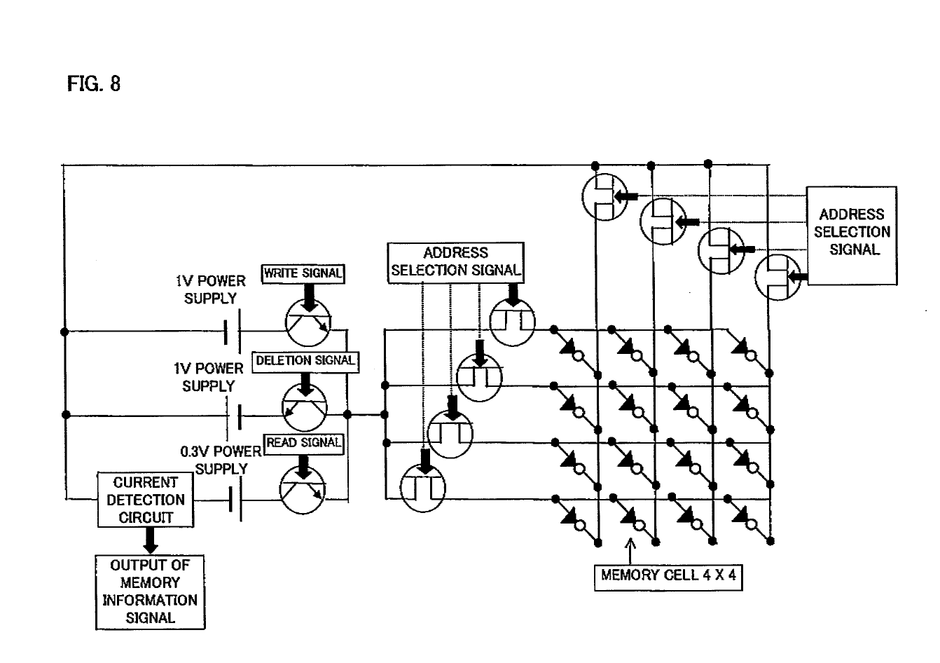

FIG. 8 shows an example of a 4×4-memory fundamental circuit using the nonvolatile memory according to the present invention.

Each memory element is a two-electrode type. Therefore, as in the case of a core memory used in an early computer, the fundamental circuit is a simple circuit in which (4+4) transistor switches are operated in response to two pairs of address selection signals for selecting row and column of memory addresses.

Writing, reading, and deleting can be performed by only switching of the applied voltage. Therefore, a simple circuit including three transistor switches for switching the voltage among 1 V, 0.2 V, and −1 V in response to signals (write signal, read signal, and deletion signal) corresponding to the respective operations is provided.

Table 1 shows a summary of characteristic comparison between the nonvolatile memory according to the present invention and a conventional memory device. As is apparent from Table 1, the nonvolatile memory according to the present invention solves all the above-mentioned problems required for the universal memory.

TABLE 1

| | Nonvolatile memory | | | | | | |
|---|---|---|---|---|---|---|---|
| | Present | | | | | | |
| | inventtion | Flash | | | | | |
| | (HoFET- | memory | | | | Volatile memory | |
| | RAM) | (MOSFET) | FeRAM | MRAM | OUM | SRAM | DRAM |
| Reading | High | Middle- | Middle | High | High | High | Middle |
| | speed | high | speed | speed | speed | speed | speed |
| | | speed | | | | | |
| Writing | High | Low- | Middle | High | High | High | Middle |
| | speed | speed | speed | speed | speed | speed | speed |
| Nonvolatility | Yes | Yes | Middle | Yes | Yes | No | No |
| Refresh | Unnecessary | Unnecessary | Unnecessary | Unnecessary | Unnecessary | Unnecessary | Necessary |
| Cell area | 0.04 | 0.04-0.08 | 0.2 | 0.2 | 0.1 | 0.4 | 0.1 |
| (μm²) | | | | | | | |
| Integration | Equivalent | Multi- | Bad | Highly | Highly | Bad | Close to |
| degree | to | value | | expected | expected | | limit |
| | OUM | expected | | | | | |
| Low- | Possible | Impossible | Limited | Possible | Possible | Possible | Limited |
| voltage | | | | | | | |
| operation | | | | | | | |
| Operation | 10 or | 10-100 | 10 or | 10 or | 10 or | 10-80 | 100 |
| current | less | | more | more | more | | |
| (mA) | | | | | | | |

### INDUSTRIAL APPLICABILITY

Because the memory current is directly controlled, the nonvolatile memory according to the present invention can be switched at high speed and power consumption thereof is small. As a result, according to the present invention, high-speed access, high integration, and small-size battery driving can be realized and a low-voltage and low-power-consumption nonvolatile memory can be provided.

The nonvolatile memory according to the present invention has the simple bipolar element including no gate electrode and thus the aluminum substrate can be used for lower electrode wiring. Therefore, memory wiring is very simple and a reduction in size is easily realized. The general-purpose aluminum material for a silicon semiconductor process is used, so conventional manufacturing facilities can be employed without any modification.

The array of the nano-holes which are formed in the aluminum anodic oxide coating and two-dimensionally arranged at regular intervals can be used as the memory cell array with a state where the nano-holes are arranged. Therefore, in the memory manufacturing according to the present invention, most of complicated fine processing can be replaced by self-organized formation, so there is an advantage that productivity can be increased.

In addition, there is an advantage that a doping technique essential for conventional silicon semiconductor is unnecessary and a rear element such as a compound semiconductor is unnecessary because materials are aluminum, general-purpose electrode materials, insulating materials, electromagnetic wave shield materials, and the like.

1. A non-volatile memory, comprising;
a pair of metal electrodes; and
a nano-hole-containing metal oxide film having a film thickness of 0.05 μm to 5 μm, which has a honeycomb structure and is provided between the pair of metal electrodes in a Schottky junction state, to use an interface state formed in a partition wall of the nano-hole-containing metal oxide film as a memory charge holder.

2. A non-volatile memory according to claim 1, wherein the nano-hole-containing metal oxide film comprises a nano-hole having a diameter of 10 nm to 150 nm which is formed by anodic oxidation process of a surface of aluminum or titanium.

3. A non-volatile memory according to claim 1 or 2, wherein the nano-hole-containing metal oxide film is divided by grooves to produce memory cells, each including two or three or more nano-holes formed by anodic oxidation process, which are insulated from one another.

4. A non-volatile memory according to claim 1 or 2, wherein the pair of metal electrodes comprise a Schottky electrode formed by joining metal to an upper end portion of a partition wall of the nano-hole-containing metal oxide film and a substrate electrode including a base metal of an oxide film of aluminum or titanium.

5. A non-volatile memory according to claim 1 or 2, wherein memory current control is directly performed by destroying and restoring a Schottky barrier based on a presence or absence of trap charge.

6. A non-volatile memory, comprising:
a substrate electrode;
a nano-hole-containing metal oxide film formed by anodic oxidation of a surface of the substrate electrode; and
a metal electrode formed to an upper end portion of a partition wall of the nano-hole-containing metal oxide film by Schottky junction,
wherein the nano-hole-containing metal oxide film has a structure in which a plurality of double Schottky barriers are formed in parallel.
